(19) United States
(12) Patent Application Publication
(10) Pub. No.: US 2024/0215351 A1
(43) Pub. Date: Jun. 27, 2024

(54) DISPLAY DEVICE

(71) Applicant: LG Display Co., Ltd., Seoul (KR)

(72) Inventors: SeungHwan SHIN, Jeonju-si (KR); WonHo LEE, Paju-si (KR); YoungMin JEONG, Paju-si (KR)

(73) Assignee: LG Display Co., Ltd., Seoul (KR)

(21) Appl. No.: 18/386,887

(22) Filed: Nov. 3, 2023

(30) Foreign Application Priority Data
Dec. 26, 2022 (KR) 10-2022-0184710

(51) Int. Cl. H10K 59/131

(52) U.S. Cl. CPC H10K 59/131

(57) ABSTRACT

A display device includes a display panel including pixels and a data driver configured to supply a data signal to the pixels. The display panel includes data lines, a high potential voltage line, and one or more reference voltage lines. Each of the pixels includes first to fourth sub pixels, and the data lines include first to fourth data lines which supply the data signals to the first to fourth sub pixels, respectively, and extend along a second direction. Further, each of the first to fourth sub pixels includes a light emitting diode and a circuit element configured to drive the light emitting diode. The first to fourth data lines are disposed between the circuit elements of two adjacent sub pixels extending along a first direction different from the second direction, among the first to fourth sub pixels.

### CROSS-REFERENCE TO RELATED APPLICATIONS

This application claims priority to Korean Patent Application No. 10-2022-0184710 filed on Dec. 26, 2022, in the Korean Intellectual Property Office, the entire disclosure of which is hereby expressly incorporated by reference into the present application.

### BACKGROUND

### Field

The present disclosure relates to a display device, and more particularly, to a display device which is capable of being driven at a high driving frequency.

### Discussion of the Related Art

A display device can include a display panel including a plurality of sub pixels and a driver for driving the display panel. The driver can include a gate driver configured to supply a gate signal to the display panel and a data driver configured to supply a data signal to the display panel. When the gate signals and data signals are supplied to the sub pixels included in the display panel, the sub pixels emit light to display images.

In recent years, as the size of the display panel is increased, a need to smoothly drive the display panel exists. One way to accomplish this is to drive the display panel in a double rate driving (DRD) manner which increases a driving frequency of the display panel.

As described above, when the driving frequency of the display panel is increased, a time to charge a voltage (data voltage) corresponding to a data signal in a corresponding sub pixel can be sharply reduced. Accordingly, there can be a limitation in that data may not be fully charged in the corresponding sub pixel, which can cause an issue in the displaying performance of the display panel.

### SUMMARY OF THE DISCLOSURE

One object of the present disclosure is to provide an improved display device with a high driving frequency, which can address the above-identified limitations and other issues associated with the related art.

Another object of the present disclosure is to provide a display device with a large-size organic light emitting diode (OLED) display panel which implements 120 Hz of double rate driving (DRD) used therein.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a display device includes a display panel in which a plurality of pixels is disposed, a data driver configured to supply a data signal to the pixels, and a gate driver configured to supply a gate signal to the pixels. The display panel includes data lines, gate lines, and a high potential voltage line, and one or two or more reference voltage lines, where each of the pixels includes first to fourth sub pixels and the data lines include first to fourth data lines which supply the data signal to the first to fourth sub pixels. Further, the first to fourth data lines are disposed between circuit elements provided in the first to fourth sub pixels which are disposed to be adjacent along a first direction, the high potential voltage line and one or two or more reference voltage lines are disposed between light emitting diodes provided in the first to fourth sub pixels, and a circuit element and a light emitting diode which configure each of the first to fourth sub pixels can be disposed along a first direction.

Other detailed matters of the exemplary embodiments are included in the detailed description and the drawings.

According to the exemplary embodiments of the present disclosure, the display device can reduce a load of a data line as compared with a design which bundles data lines, by allocating the data lines in an efficient manner.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to an embodiment of the present disclosure;

FIG. 2 is a circuit diagram illustrating an example of a sub pixel according to an embodiment of the present disclosure;

FIG. 3 is a block diagram illustrating a pixel area of a display device according to an example of the present disclosure;

FIG. 4A is a plan view illustrating a circuit structure of a pixel area of a display device according to an example of the present disclosure;

FIG. 4B is a plan view illustrating a repair line of FIG. 4A according to an example of the present disclosure;

FIG. 5 is a plan view illustrating a circuit structure including a data bridge in a display panel according to an example of the present disclosure; and

FIG. 6 is a plan view illustrating a circuit structure for driving a sub pixel in a display panel according to an example of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “over”, “above”, “below”, “under”, and “next”, one or more parts can be positioned between the two parts unless the terms are used with the term “immediately” or “directly”.

When an element or layer is disposed “on” or “over” another element or layer, one or more other layer(s) or element(s) can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The term “exemplary” is used to mean an example, and is interchangeably used with the term “example”. Further, embodiments are example embodiments and aspects are example aspects. Any implementation described herein as an “example” is not necessarily to be construed as preferred or advantageous over other implementations.

The features of various embodiments of the present disclosure can be partially or entirely adhered to or combined with each other and can be interlocked and operated in technically various ways, and the embodiments can be carried out independently of or in association with each other.

A transistor used for a display device according to exemplary embodiments of the present disclosure can be implemented by any one transistor among n-channel transistors such as N-channel metal-oxide semiconductors (NMOS) and p-channel transistors such as P-channel metal-oxide semiconductors (PMOS). The transistor can be implemented by an oxide semiconductor transistor having an oxide semiconductor as an active layer or a low temperature poly-silicon (LTPS) transistor having an LTPS as an active layer. The transistor can include at least a gate electrode, a source electrode, and a drain electrode. The transistor can be implemented as a thin film transistor (TFT) on a display panel. In the transistor, carriers flow from the source electrode to the drain electrode. In the case of the n-channel transistor (e.g., NMOS), since the carriers are electrons, in order to allow the electrons to flow from the source electrode to the drain electrode, a source voltage can be lower than a drain voltage. The current in the n-channel transistor (e.g., NMOS) can flow from the drain electrode to the source electrode and the source electrode can serve as an output terminal. In the case of the p-channel transistor (e.g., PMOS), since the carriers are holes, in order to allow the holes to flow from the source electrode to the drain electrode, a source voltage is higher than a drain voltage. In the p-channel transistor (e.g., PMOS), the holes flow from the source electrode to the drain electrode so that current can flow from the source to the drain and the drain electrode can serve as an output terminal. Accordingly, the source and the drain can be switched in accordance with the applied voltage so that it should be noted that the source and the drain of the transistor are not fixed. In the present specification, it is assumed that transistors used herein can be n-channel transistors (e.g., NMOS) only as an example, but are not limited thereto in that other n-type transistors and/or p-channel transistors can be used and thus a circuit configuration can be changed accordingly.

A gate signal of transistors which are used as switching elements can swing between a gate-on voltage and a gate-off voltage. In an example, the gate-on voltage is set to be higher than a threshold voltage Vth of the transistor and the gate off voltage can be set to be lower than the threshold voltage Vth of the transistor, but other variations are possible. The transistor is turned on in response to the gate-on voltage and can be turned off in response to the gate-off voltage. In the case of the n-channel transistor (e.g., NMOS), the gate-on voltage can be a gate high voltage VGH and the gate-off voltage can be a gate low voltage VGL. In the case of the p-channel transistor (e.g., PMOS), the gate-on voltage can be a gate low voltage VGL and the gate-off voltage can be a gate high voltage VGH.

Hereinafter, various exemplary embodiments of the present disclosure will be described in detail with reference to accompanying drawings. All components of each display device according to all embodiments of the present disclosure are operatively coupled and configured.

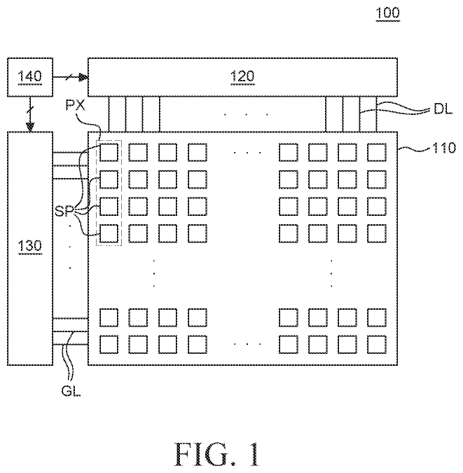

FIG. 1 is a block diagram illustrating a display device according to an embodiment of the present disclosure.

Referring to FIG. 1, a display device 100 according to an exemplary embodiment of the present disclosure can include a display panel 110, a gate driver 120, a data driver 130, and a timing controller 140. The display device 100 can include other elements/components such as a host system, a power supply, etc.

The display panel 110 can display an image. The display panel 110 in its entirety or a portion thereof can be referred to as a display unit or a pixel unit. The display panel 110 can include various circuits, signal lines, and light emitting diodes disposed on a substrate. The display panel 110 can include a plurality of pixels PX that are divided by a plurality of data lines DL and a plurality of gate lines GL intersecting each other and are connected to the plurality of data lines DL and the plurality of gate lines GL. The data lines DL generate data signals and the gate lines GL generate gate signals.

The display panel 110 can include an active area (or display area) in which an image is displayed and a non-active area (or non-display area) in which various signal lines or pads are formed. The non-active area is located at the outside of the active area, and can surround the active area entirely or in part only.

The display panel 110 can be implemented by a display panel used in various display devices, such as a liquid crystal display device, an organic light emitting display device, or an electrophoretic display device. Hereinafter, it is described that the display panel 110 is a panel used in the organic light emitting display device, but the exemplary embodiment of the present disclosure is not limited thereto.

The display panel 110 can include the plurality of pixels PX disposed in the active area. Each of the plurality of pixels PX can be electrically connected to a corresponding gate line, among the gate lines GL, and a corresponding data line, among the data lines DL. Therefore, a gate signal and a data signal can be applied to each pixel PX, through the corresponding gate line and the corresponding data line. Further, each pixel PX can implement the gray scale by the applied gate signal and data signal and finally, the image can be displayed in the active area by the gray scales displayed by the pixels PX.

Further, each of the plurality of pixels PX can include a plurality of sub pixels SP. The sub pixels SP included in one pixel PX can emit different color light. For example, the sub pixels SP can include a red sub pixel, a green sub pixel, a blue sub pixel, and a white sub pixel, but is not limited thereto. In one pixel PX, a combination of red, green, and blue sub pixels with or without a white sub pixel can be included. As such, the plurality of sub pixels SP can configure one pixel PX. For example, the red sub pixel, the green sub pixel, the blue sub pixel, and the white sub pixel can configure one pixel PX, and the display panel 110 can include the plurality of such pixels PX arranged in a matrix configuration or other configurations.

The timing controller 140 (also referred to herein as a timing control circuit) can receive timing signals, such as a vertical synchronization signal, a horizontal synchronization signal, a data enable signal, or a dot clock by a receiving circuit such as a low-voltage differential signaling (LVDS) or transition-minimized differential signaling (TMDS) interface connected to the outside (for example, a host system). The timing controller 140 can generate and output timing control signals based on the input timing signal to control the data driver 130 and the gate driver 120.

The data driver 130 (also referred to herein as a data driving circuit) can supply a data signal to the plurality of sub pixels SP. To this end, the data driver 130 can include at least one source drive IC (integrated circuit). The source drive IC can be supplied with digital video data and source timing control signals from the timing controller 140. The source drive IC converts the digital video data into a gamma voltage in response to a source timing control signal to generate and supply a data signal to the sub pixels SP through the data lines DL of the display panel 110.

The source drive IC can be connected to the data line(s) DL of the display panel 110 by a chip on glass (COG) process or a tape automated bonding (TAB) process. Further, the source drive IC is formed on the display panel 110 or can be formed on a separate printed circuit board (PCB) substrate that is connected to the display panel 110.

The gate driver 120 (also referred to herein as a gate driving circuit, a scan driver, or a scan driving circuit) can supply a gate signal to the plurality of sub pixels SP. The gate driver 120 can include a level shifter and a shift register. The level shifter shifts a level of a clock signal input at a transistor-transistor-logic (TTL) level from the timing controller 140 and then can supply the clock signal to the shift register. The shift register can be formed in the non-display area of the display panel 110, by a gate-in-panel (GIP) manner, but is not limited thereto. The shift register can be configured by a plurality of stages which shift the gate signal to output, in response to the clock signal and the driving signal. The plurality of stages included in the shift register can sequentially output the gate signal through a plurality of output terminals.

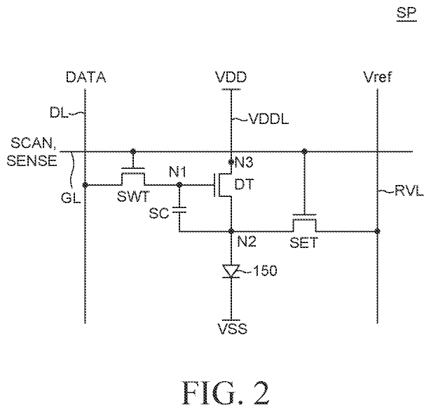

Hereinafter, a driving circuit (pixel circuit) for driving one sub pixel SP of a display device according to an example of the present disclosure will be described in more detail with reference to FIG. 2. The driving circuit configuration of FIG. 2 can be used in the display device 100 of FIG. 1 or in any other display device of the present disclosure.

FIG. 2 is a circuit diagram illustrating an example of a sub pixel of a display device according to the present disclosure.

Referring to FIG. 2, the sub pixel SP can include a switching transistor SWT, a sensing transistor SET, a driving transistor DT, a storage capacitor SC, and a light emitting diode 150.

The light emitting diode 150 can include an anode, an emission layer, and a cathode. For example, the emission layer can be an organic layer and the organic layer can include one or more of various organic layers such as a hole injection layer, a hole transport layer, an organic light emitting layer, an electron transport layer, and an electron injection layer. The anode (or one end) of the light emitting diode 150 can be connected to the driving transistor DT (for example, an output terminal of the driving transistor DT) and a low potential voltage VSS can be applied to the cathode (or another end) of the light emitting diode 150.

In the meantime, even though in FIG. 2 it is described that the light emitting diode 150 is an organic light emitting diode, the exemplary embodiment of the present disclosure is not limited thereto. For example, the light emitting diode 150 can be an inorganic light emitting diode (for example, an LED).

The driving transistor DT supplies a driving current to the light emitting diode 150 to allow the light emitting diode 150 to emit light. The driving transistor DT can include a gate electrode connected to a first node N1, a source electrode (an output terminal) connected to a second node N2, and a drain electrode (an input terminal) connected to a third node N3. The first node N1 to which the gate electrode of the driving transistor is connected is connected to the switching transistor SWT. The third node N3 to which the drain electrode of the driving transistor DT is connected is connected to a high potential voltage line VDDL for receiving a high potential voltage VDD. The second node N2 to which the source electrode of the driving transistor DT is connected can be connected to the anode of the light emitting diode 150.

The switching transistor SWT can transmit the data signal DATA (data voltage) from the corresponding data line DL to the gate electrode of the driving transistor DT at the first node N1. The switching transistor SWT can include a gate electrode connected to the corresponding gate line GL, a drain electrode connected to the data line DL, and a source electrode connected to the gate electrode of the driving transistor DT at the first node N1. The switching transistor SWT is turned on by a scan signal SCAN (gate signal) supplied from the gate line GL to transmit the data signal DATA (data voltage) supplied from the data line DL to the gate electrode of the driving transistor DT at the first node N1.

The storage capacitor SC can maintain a voltage (data voltage) corresponding to the data signal DATA for one frame. One electrode of the storage capacitor SC is connected to the first node N1 and the other electrode is connected to the second node N2. For example, the storage capacitor SC can be connected between the gate electrode and the source electrode of the driving transistor DT.

In the meantime, as a driving time of each sub pixel SP is increased, the circuit element such as the driving transistor DT can be degraded. Accordingly, a unique characteristic value of the circuit element, such as the driving transistor DT, can be changed. Here, the unique characteristic value of the circuit element can include a threshold voltage Vth of the driving transistor DT or a mobility a of the driving transistor DT. The change in the characteristic value of the circuit element can cause a luminance change of the corresponding sub pixel SP. Accordingly, the change in the characteristic value of the circuit element can be considered as the same or similar concept as the luminance change of the sub pixel SP.

Further, the degree of the change in the characteristic values between circuit elements of each sub pixel SP can vary depending on a degree of degradation of each circuit element. Such a difference in the changing degree of the characteristic values between the circuit elements can cause a luminance deviation between the sub pixels SP. Accordingly, the characteristic value deviation between the circuit elements of the sub pixels SP can be considered as the same or similar concept as the luminance deviation between the sub pixels SP. The change in the characteristic values of the circuit elements (e.g., the luminance change of the sub pixel SP) and the characteristic value deviation between the circuit elements (e.g., the luminance deviation between the sub pixels SP) can cause limitations such as the degradation of the accuracy for luminance expressiveness of the sub pixel SP or screen abnormality.

Therefore, the display device 100 (see FIG. 1) according to the exemplary embodiment of the present disclosure provides a sensing function of sensing a characteristic value for the sub pixel SP and a compensating function of compensating for the characteristic value of the sub pixel SP using the sensing result.

For example, as illustrated in FIG. 2, the sub pixel SP further can include a sensing transistor SET for controlling a voltage state of the source electrode of the driving transistor DT.

Referring to FIG. 2, the sensing transistor SET is connected between the source electrode of the driving transistor DT and a reference voltage line RVL configured to supply a reference voltage Vref, and can include a gate electrode which is connected to the gate line GL. Therefore, the sensing transistor SET is turned on by the sensing signal SENSE applied through the gate line GL to supply the reference voltage Vref supplied through the reference voltage line RVL to the source electrode of the driving transistor DT. Further, the sensing transistor SET can be utilized as one of voltage sensing paths for the source electrode of the driving transistor DT.

As described above, the reference voltage Vref is applied to the source electrode of the driving transistor DT by the sensing transistor SET which is turned on by the sensing signal SENSE. Further, a voltage for sensing the threshold voltage Vth of the driving transistor DT or the mobility α of the driving transistor DT can be detected by the reference voltage line RVL.

Also, the data driver 130 (see FIG. 1) of the display device 100 can compensate for the data voltage DATA in accordance with a variation of the threshold voltage Vth of the driving transistor DT or the mobility a of the driving transistor DT.

In the meantime, as illustrated in FIG. 2, the switching transistor SWT and the sensing transistor SET included in the sub pixel SP can share one gate line GL. For example, the switching transistor SWT and the sensing transistor SET are connected to the same gate line GL to be supplied with the same signal (gate signal). However, for the convenience of description, in the above description, a signal which is applied to the gate electrode of the switching transistor SWT is referred to as a scan signal SCAN and a signal which is applied to the gate electrode of the sensing transistor SET is referred to as a sensing signal SENSE. However, the scan signal SCAN and the sensing signal SENSE applied to one sub pixel SP are the same signal which is transmitted through the same gate line GL.

Also, this is just illustrative so that the exemplary embodiment of the present disclosure is not limited thereto. In another example, only the switching transistor SWT is connected to the gate line GL while the sensing transistor SET can be connected to a separate sensing line. Therefore, the scan signal SCAN is applied to the switching transistor SWT through the gate line GL whereas the sensing signal SENSE can be applied to the sensing transistor SET through the separate sensing line. Other variations are possible.

Hereinafter, as illustrated in FIG. 2, it will be described that the switching transistor SWT and the sensing transistor SET included in the sub pixel SP share one same gate line GL and thus the same signal from the one same gate line GL would be applied to the switching transistor SWT and the sending transistor SET. Therefore, hereinafter, the scan signal SCAN and the sensing signal SENSE are defined as gate signals GATE1, GATE2, GATE3, and GATE4.

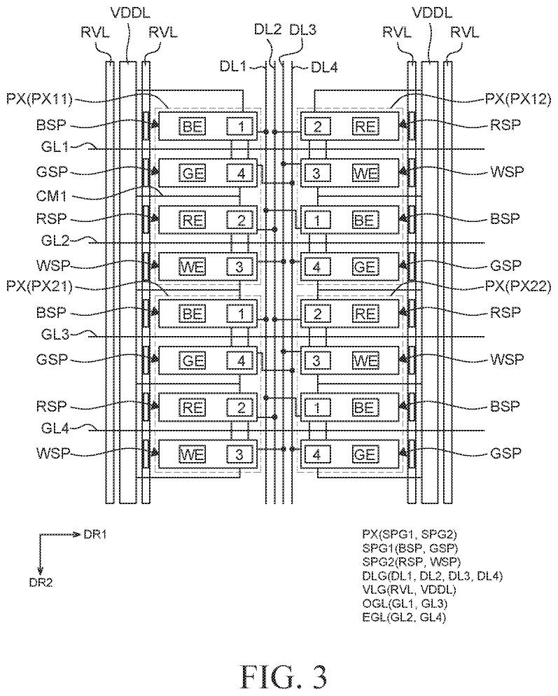

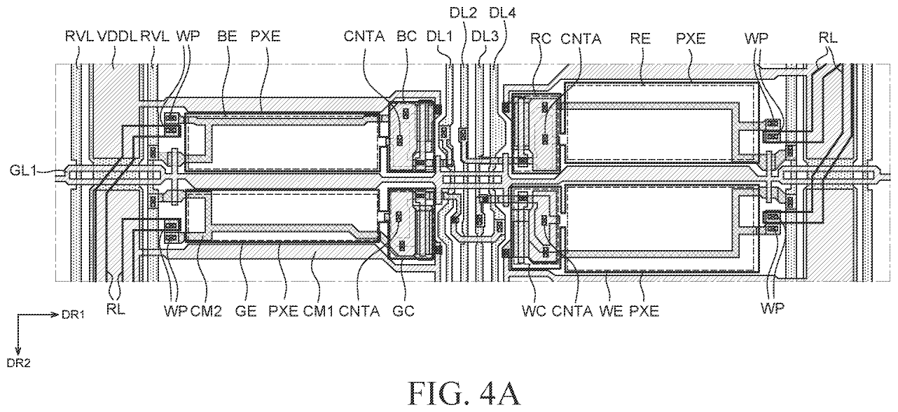

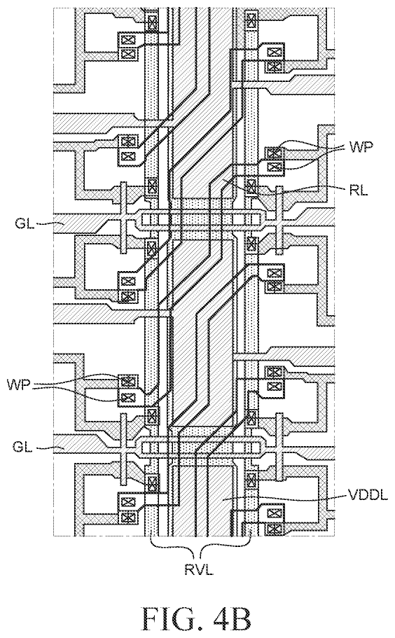

FIG. 3 is a block diagram illustrating a pixel area of a display panel according to an example of the present disclosure, FIG. 4A is a plan view illustrating an example of a circuit structure of the pixel area of FIG. 3, and FIG. 4B is a plan view illustrating a repair line of FIG. 4A. The display panel of FIGS. 3-4B can be the display panel of FIG. 1.

Referring to FIGS. 3, 4A, and 4B, the display panel can include a plurality of pixel groups which are repeatedly disposed on a substrate. Each pixel group can include first pixels PX11 and PX21 and second pixels PX12 and PX22. Each of the first pixels PX11 and PX21 can include four sub pixels according to a first placement. Each of the second pixels PX12 and PX22 can include four sub pixels according to a second placement. According to the first placement, for example, blue, green, red, and white sub pixels can be sequentially disposed along a second direction DR2. According to the second placement, for example, red, white, blue, and green sub pixels can be sequentially disposed along the second direction DR2. In this specification, a sub pixel which outputs blue color can be referred to as as a first sub pixel BSP, a sub pixel which outputs red color can be referred to as as a second sub pixel, a sub pixel which outputs white color can be referred to as as a third sub pixel WSP, and a sub pixel which outputs green color can be referred to as a fourth sub pixel GSP.

In one exemplary embodiment, the first pixels PX11 and PX21 and the second pixels PX12 and PX22 can include a first sub pixel group SPG1 and a second sub pixel group SPG2, respectively. Each of the first sub pixel group SPG1 and the second sub pixel group SPG2 can include two sub pixels. The first sub pixel group SPG1 can be configured by two sub pixels which do not match or are different from the two sub pixels of the second sub pixel group SPG2. For example, the first sub pixel group SPG1 can include a first sub pixel BSP and a fourth sub pixel GSP, whereas the second sub pixel group SPG2 can include a second sub pixel RSP and a third sub pixel WSP.

In one exemplary embodiment, the sub pixel group included in the first pixels PX11 and PX21 and the sub pixel group included in the second pixels PX12 and PX22 are alternately disposed with each other. For example, the sub pixel groups included in each of the first pixels PX11 and PX21 can be located in the order of a first sub pixel group SPG1 (composed of, e.g., BSP and GSP) and a second sub pixel group SPG2 (composed of, e.g., RSP and WSP) along the second direction DR2. Further, the sub pixel groups included in each of the second pixels PX12 and PX22 can be located in the order of a second sub pixel group SPG2 (composed of, e.g., RSP and WSP) and a first sub pixel group SPG1 (composed of, e.g., BSP and GSP) along the second direction DR2.

In the meantime, in one exemplary embodiment, pixels which are disposed along the substantially same column can include sub pixels which are disposed in the substantially same order. For example, the pixels can commonly include four sub pixels which are disposed along the first placement (in which blue, green, red, and white are sequentially disposed along the second direction DR2). Further, the pixels can commonly include four sub pixels which are disposed along the second placement (in which red, white, blue, and green are sequentially disposed along the second direction DR2).

In one exemplary embodiment, the sub pixels extend along the first direction DR1. The first sub pixel BSP, the second sub pixel RSP, the third sub pixel WSP, and the fourth sub pixel GSP extend along the first direction DR1 and can be disposed in a predetermined order along the second direction DR2. Therefore, the first sub pixel BSP and the second sub pixel RSP can be opposite to each other with respect to a short side and the first sub pixel BSP and the fourth sub pixel GSP can be opposite to each other with respect to a long side. Further, the third sub pixel WSP and the second sub pixel RSP can be opposite to each other with respect to a long side and the third sub pixel WSP and the fourth sub pixel GSP can be opposite to each other with respect to a short side. Other variations are possible.

In one exemplary embodiment, first to fourth gate lines GL1, GL2, GL3, and GL4 among the plurality of gate lines GL can extend along the first direction DR1. In this regard, FIG. 3 illustrates the first gate line GL1, the second gate line GL2, the third gate line GL3, and the fourth gate line GL4 all extending along the first direction DR1, where the gate lines GL1, GL2, GL3, and GL4 are sequentially disposed and located along the second direction DR2. Even though the display panel according to various exemplary embodiments of the present disclosure can include a large number of gate lines, for the convenience of description, a portion of such gate lines is illustrated, e.g., the four gate lines GL1, GL2, GL3, and GL4, but various exemplary embodiments are not limited thereto.

In one exemplary embodiment, the first and third gate lines GL1 and GL3 can be disposed between the first sub pixel BSP and the fourth sub pixel GSP which configure part of the first pixels PX11 and PX21. Further, the first and third gate lines GL1 and GL3 can be disposed between the second sub pixel RSP and the third sub pixel WSP which configure part of the second pixels PX12 and PX22. In one exemplary embodiment, the second and fourth gate lines GL2 and GL4 can be disposed between the second sub pixel RSP and the third sub pixel WSP which configure the remaining part of the first pixels PX11 and PX21. Further, the second and fourth gate lines GL2 and GL4 can be disposed between the first sub pixel BSP and the fourth sub pixel GSP which configure the remaining part of the second pixels PX12 and PX22.

The first gate line GL1 can be disposed between the second sub pixel RSP and the third sub pixel WSP with respect to an N-th column (N is 2K where K is a natural number such as a positive integer) and the first gate line GL1 can be disposed between the first sub pixel BSP and the fourth sub pixel GSP with respect to an M-th column (M is 2K where K is a natural number such as a positive integer). Further, the second gate line GL2 can be disposed between the first sub pixel BSP and the fourth sub pixel GSP with respect to the N-th column and the second gate line GL2 can be disposed between the second sub pixel RSP and the third sub pixel WSP with respect to the M-th column.

In one exemplary embodiment, the first gate line GL1 can be electrically connected to circuit elements of each of the sub pixels which configure the first pixels PX11 and PX21 and the second pixels PX12 and PX22. The first sub pixel BSP can include a first circuit element BC and a first light emitting diode, the second sub pixel RSP can include a second circuit element RC and a second light emitting diode, the third sub pixel WSP can include a third circuit element WC and a third light emitting diode, and the fourth sub pixel GSP can include a fourth circuit element GC and a fourth light emitting diode. For example, the first gate line GL1 can be electrically connected to the first circuit element BC and the fourth circuit element GC which are associated with the first pixels PX11 and PX21. The first gate line GL1 can be electrically connected to the second circuit element RC and the third circuit element WC which are associated with the second pixels PX12 and PX22. Further, the second gate line GL2 can be electrically connected to the second circuit element RC and the third circuit element WC which are associated with the first pixels PX11 and PX21. The second gate line GL1 can be electrically connected to the first circuit element BC and the fourth circuit element GC which are associated with the second pixels PX12 and PX22.

In one exemplary embodiment a first group of gate lines OGL can include a first gate line GL1 and a third gate line GL3. The first group of gate lines OGL can be electrically connected to the first circuit element BC and the fourth circuit element GC which are associated with the first pixels PX11 and PX21, and can be electrically connected to the second circuit element RC and the third circuit element WC which are associated with the second pixels PX12 and PX22. A second group of gate lines EGL can be electrically connected to the second circuit element RC and the third circuit element WC which are associated with the first pixels PX11 and PX21 and can be electrically connected to the first circuit element BC and the fourth circuit element GC which are associated with the second pixels PX12 and PX22.

Here, the first to fourth light emitting diodes can correspond to first to fourth emission areas RE, BE, GE, and WE, respectively.

Agate line which is electrically connected to each of the circuit elements can apply a gate signal to turn on a switching transistor SWT (see FIG. 2) and/or the sensing transistor SET (see FIG. 2).

In one exemplary embodiment, the gate line is divided into multiple branches (e.g., two branches) in an area which is disposed to intersect other wiring lines (for example, a high potential voltage line VDDL, a reference voltage line, and a data line) and can be combined as one wiring line in an area which does not intersect other wiring lines. Here, two divided branches of the gate line can be disposed to be substantially parallel to each other.

In one exemplary embodiment, the data lines DL1, DL2, DL3, and DL4 can extend along the second direction DR2. For instance, FIG. 3 illustrates the first data line DL1, the second data line DL2, the third data line DL3, and the fourth data line DL4 which are sequentially disposed along the first direction DR1 and which extend along the second direction DR2. Even though the display panel according to various exemplary embodiments of the present disclosure can include a larger number of data lines, for the convenience of description, the four data lines are illustrated, but various exemplary embodiments are not limited thereto.

In one exemplary embodiment, the first data line DL1, the second data line DL2, the third data line DL3, and the fourth data line DL4 can be disposed between the circuit elements (for example, the second circuit element RC and the third circuit element WC) included in the first pixels PX11 and PX21 and the circuit elements (for example, the first circuit element BC and the fourth circuit element GC) included in the second pixels PX12 and PX22 as shown in FIG. 4A. To be more specific, the first data line DL1, the second data line DL2, the third data line DL3, and the fourth data line DL4 can be disposed between the first circuit element BC and the second circuit element RC. Further, the first data line DL1, the second data line DL2, the third data line DL3, and the fourth data line DL4 can be disposed between the third circuit element WC and the fourth circuit element GC.

In one exemplary embodiment, the data line can be electrically connected to circuit element of the sub pixel. For example, as shown in FIGS. 3 and 4A, the first data line DL1 can be electrically connected to the first circuit element BC of the first sub pixel BSP. For example, the second data line DL2 can be electrically connected to the second circuit element RC of the second sub pixel RSP. For example, the third data line DL3 can be electrically connected to the third circuit element WC of the third sub pixel WSP. For example, the fourth data line DL4 can be electrically connected to the fourth circuit element GC of the fourth sub pixel GSP.

A data line which is electrically connected to each of the circuit elements can apply a data signal to charge a voltage in a storage capacitor. The data line can be electrically connected to a source-drain electrode of the switching transistor, and the data signal can be transmitted to the storage capacitor via the source-drain electrode while the switching transistor is maintained in a turned-on state.

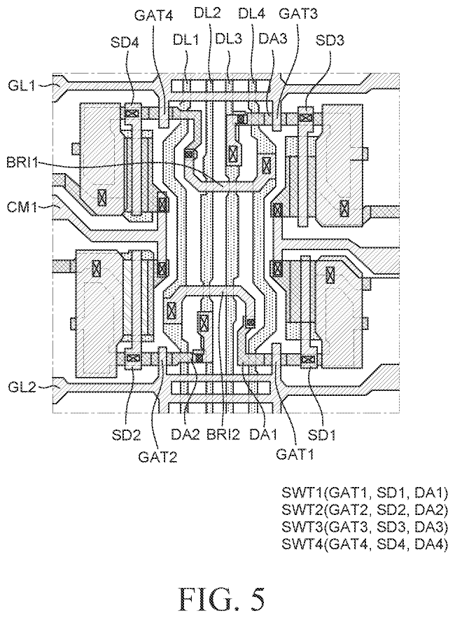

In the meantime, in one exemplary embodiment, data lines can be included in one data line group DLG (FIG. 3). The data line group DLG can be disposed between the circuit elements of the first pixel PX11 and PX21 and the circuit elements of the second pixel PX12 and PX22. The data lines included in the data line group DLG can be disposed in a predetermined order along the first direction DR1. For example, the data lines can be disposed in the order of the first data line DL1, the second data line DL2, the third data line DL3, and the fourth data line DL4 along the first direction DR1. The placement order of the data lines can be associated with the placement of the sub pixels. In accordance with a placement order of the data lines, a data bridge can be electrically connected to at least some of data lines. A data line to which the data bridge is connected can be electrically connected to a circuit element through the data bridge. An example of the data bridge will be described below with reference to FIG. 5 later.

Further, various exemplary embodiments of the present disclosure are not limited thereto, but a blue pigment or a red-blue double pigment can be deposited on one or more data lines. The pigment can be deposited so that a capacitance formed between the data line and the cathode can be minimized.

In one exemplary embodiment, the display panel can further include voltage lines. For example, the voltage lines can include a high potential voltage line VDDL and a reference voltage line RVL. The high potential voltage line VDDL and the reference voltage line RVL which are applied to the exemplary embodiment can configure one voltage line group VLG (FIG. 3) and can be disposed on the display panel in the unit of voltage line group VLG.

In one exemplary embodiment, the voltage line group VLG can include the high potential voltage line VDDL and one or two or more reference voltage lines RVL. The reference voltage line RVL is not limited thereto and can be disposed as a single line or a plurality of lines. According to the example illustrated in FIG. 3, the voltage line can include one high potential voltage line VDDL and two reference voltage lines RVL.

In one exemplary embodiment, the high potential voltage line VDD can be disposed between the reference voltage lines RVL. For example, one reference line RVL can be disposed at each of the left side and the right side of the high potential voltage line VDDL as shown in FIG. 3. Here, the reference voltage line RVL can be combined as one wiring line at one end of the display panel, but various exemplary embodiments of the present disclosure are not limited thereto.

In one exemplary embodiment, the high potential voltage line VDDL and the reference voltage lines RVL can be electrically connected to the circuit element of each sub pixel. In one exemplary embodiment, the high potential voltage line VDDL and the reference voltage lines RVL can be electrically connected to the circuit elements through a connection member. Here, the connection member of the high potential voltage line VDDL can be defined as a first connection member CM1 and the connection member of the reference voltage line RVL can be defined as a second connection member CM2 as shown in FIG. 4A. In one exemplary embodiment, the first connection member CM1 includes a conductive material or can be formed of the conductive material and the second connection member CM2 includes a semiconductor material or can be formed of the semiconductor material. For example, the second connection member CM2 can be formed with a structure in which a transparent conductive oxide thin film is laminated on a transparent oxide semiconductor thin film.

In one exemplary embodiment, one end of the first connection member CM1 is electrically connected to the high potential voltage line VDDL and the other end of the first connection member CM1 can be electrically connected to a sub pixel (specifically, a circuit element of the sub pixel).

In one exemplary embodiment, the first connection member CM1 can be electrically connected to the sub pixel (e.g., the circuit element thereof) via a side surface which is opposite to the gate line which is electrically connected to the sub pixel, with respect to the electrically connected sub pixel.

For example, referring to wiring lines which are connected to the first sub pixel BSP of the first pixels PX11 and PX21, the first and third gate lines GL1 and GL3 extend along the first direction DR1 below the first sub pixel BSP and are electrically connected to the first circuit element BC. The first connection member CM1 extends along the first direction DR1 above the first sub pixel BSP and is electrically connected to the first circuit element BC.

For example, referring to wiring lines which are connected to the fourth sub pixel GSP of the first pixels PX11 and PX21, the first and third gate lines GL1 and GL3 extend along the first direction DR1 above the fourth sub pixel GSP and are electrically connected to the fourth circuit element GC. The first connection member CM1 is electrically connected to the second circuit element GC below the fourth sub pixel GSP.

In one exemplary embodiment, the first connection member CM1 can be electrically connected to one or two sub pixels (specifically, the circuit element). For example, the first connection member CM1 which is connected to the sub pixel disposed at an edge of the display panel can be electrically connected to one sub pixel disposed at an edge. For example, the first connection member CM1 which is connected to a sub pixel located in a remaining part of the display panel other than the edge thereof can be electrically connected two sub pixels located on both upper and lower sides with the first connection member CM1 therebetween.

To be more specific, referring to the second sub pixel RSP and the fourth sub pixel GSP of the pixel PX11, the first connection member CM1 extends along the first direction DR1 between the second sub pixel RSP and the fourth sub pixel GSP. The extending first connection member CM1 extends along the second direction DR2 from one end and is electrically connected to the second sub pixel RSP and the fourth sub pixel GSP.

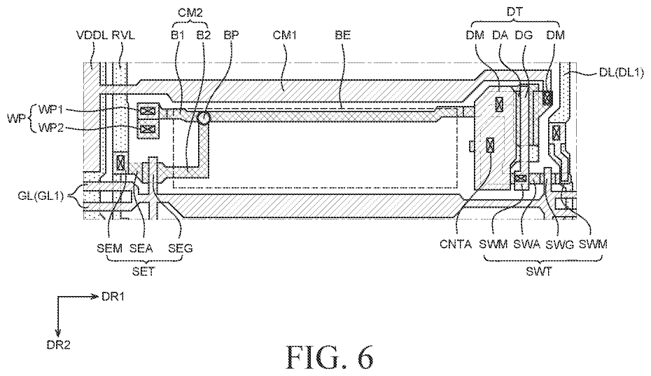

Referring to the third sub pixel WSP of the pixel PX11 and the first sub pixel BSP of the pixel PX21 adjacent thereto along the second direction DR2, the first connection member CM1 extends along the first direction DR1 between the third sub pixel WSP and the first sub pixel BSP. Further, the first connection member CM1 extends along the second direction DR2 from one end to be electrically connected to the third sub pixel WSP and the first sub pixel BSP. The first connection member can be formed in the substantially same direction (the second direction DR2) as the switching gate electrode and the driving gate electrode of the present disclosure to be described below with reference to FIG. 6.

In one exemplary embodiment, the first connection member CM1 extends along the first direction DR1 and can vertically extend along the second direction DR2 at an edge adjacent to the data line.

In one exemplary embodiment, the first connection member CM1 does not overlap at least partially the data lines (for example, DL1, DL2, DL3, and DL4). The first connection member CM1 can extend along the first direction DR1 between the sub pixels, but is disposed not to at least partially intersect the data lines. For instance, the first connection CM1 does not intersect or overlap the data lines DL1 to DL4 disposed adjacent thereto.

In one exemplary embodiment, one end of the second connection member CM2 is electrically connected to the reference voltage line RVL and the other end of the second connection member CM2 can be electrically connected to a sub pixel (specifically, the circuit element of the sub pixel such as BC, RC, WC, or GC).

In one exemplary embodiment, the second connection member CM2 can be disposed in an area which at least partially overlaps the light emitting diode of the sub pixel electrically connected thereto. For example, referring to the first sub pixel BSP of the first pixels PX11 and PX21, the second connection member CM2 can be disposed to at least partially pass through an area in which the first light emitting diode is formed.

In the meantime, a first end of the second connection member CM2 is connected to the reference voltage line RVL, a second end thereof is connected to the circuit element of the sub pixel, and a third end thereof can be connected to a welding point WP (which will be described in more detail later with reference to FIG. 6). The second connection member CM2 is divided into a first branch B1 and a second branch B2 from a branch point BP, and the first branch B1 is connected to a first welding point WP1 and the second branch B2 can be connected to the reference voltage line RVL.

Hereinafter, a pixel electrode PXE, a repair line RL, and the welding point WP will be described with reference to FIGS. 4A and 4B. In the description with reference to FIGS. 4A and 4B, a first column and a second column refer to columns at a left side and a right side of the voltage line (for example, the high potential voltage line VDDL and the reference voltage line RVL).

Referring to FIG. 4A, a pixel electrode PXE (for example, an anode thereof) can be electrically connected to the circuit element through an anode contact hole CNTA. Each circuit element can include an anode contact hole CNTA configured to supply a current to the light emitting diode. The light emitting diode can transmit a driving current which is determined according to a voltage applied to a gate of the driving transistor to the pixel electrode PXE through the anode contact hole CNTA. The pixel electrode PXE can be disposed so as to cover at least a part of the emission area of the light emitting diode and the circuit element.

In one exemplary embodiment, the sub pixels disposed along the first column can be connected to the sub pixels which are disposed along a second column spaced apart from each other with the voltage line (for example, the high potential voltage line VDDL and the reference voltage line RVL) therebetween by the repair line RL. The sub pixels which are connected by the repair line RL can be sub pixels which express substantially the same color. Both ends of the repair line RL can be connected to the welding point WP provided in each sub pixel. The welding point WP refers to a point at which an electrical connection is formed in response to a laser irradiation. When a laser is irradiated onto the welding point WP, electrodes which are adjacent to the welding point WP can be electrically connected to each other.

The welding point WP will be described in more detail according to an embodiment of the present disclosure. The first sub pixel BSP disposed along the first column can be connected to the first sub pixel BSP disposed along the second column through the repair line RL. The second sub pixel RSP disposed along the first column can be connected to the second sub pixel RSP disposed along the second column through the repair line RL. The third sub pixel WSP disposed along the first column can be connected to the third sub pixel WSP disposed along the second column through the repair line RL. The fourth sub pixel GSP disposed along the first column can be connected to the fourth sub pixel GSP disposed along the second column through the repair line RL.

Referring to FIG. 4B, in one exemplary embodiment, the welding point WP can be disposed to be adjacent to the reference voltage line RVL. Further, the welding point WP can be disposed to be closer to the reference voltage line RVL than the data line. The repair line RL which connects the welding point WP can be connected to another welding point WP across the voltage line (for example, a high potential voltage line VDDL or a reference voltage line RVL). In view of this structure, the repair line RL can be disposed so as not to cross the data line. For instance, as shown in FIG. 4A, the repair line RL on the left side of the drawing overlaps the high potential voltage line VDDL and the reference voltage line(s) RVL shown on the left side of the drawing. Similarly, the repair line RL on the right side of the drawing overlaps the high potential voltage line VDDL and the reference voltage line(s) RVL shown on the right side of the drawing. The repair lines RL do not overlap any of the data lines DL1 to DL4 in the middle part of FIG. 4A.

Further, in one exemplary embodiment, the repair lines RL can be disposed so as not to overlap each other. For example, one repair line RL can be disposed to be spaced apart from another repair line RL. In one exemplary embodiment, the repair line RL can be formed on the same layer with the same material as the pixel electrode PXE.

Now, FIG. 5 is a plan view illustrating a circuit structure including a data bridge which can be implemented in a display panel of the present disclosure.

In this example, the display panel can include a first sub pixel BSP, a second sub pixel RSP, a third sub pixel WSP, and a fourth sub pixel GSP. The first sub pixel BSP can include a first circuit element BC, the second sub pixel RSP can include a second circuit element RC, the third sub pixel WSP can include a third circuit element WC, and the fourth sub pixel GSP can include a fourth circuit element GC.

Referring to FIG. 5, in one exemplary embodiment, the circuit element can be electrically connected to the data line. For example, the first circuit element BC can be connected to the first data line DL1, the second circuit element RC can be connected to the second data line DL2, the third circuit element WC can be connected to the third data line DL3, and the fourth circuit element GC can be connected to the fourth data line DL4.

Referring to FIG. 5, in one exemplary embodiment, the display panel can include a data bridge. The data bridge can be electrically connected to at least some of data lines. The data line and the data bridge can be disposed on different layers with an insulating film therebetween. The data bridge can be disposed so as to intersect one or two or more of data lines. For example, referring to the circuit structure illustrated in FIG. 5, a first data bridge BRI1 connected to the fourth data line DL4 is disposed so as to intersect (or cross over) the second data line DL2 and the third data line DL3. A second data bridge BRI2 connected to the first data line DL1 is disposed so as to intersect (or cross over) the second data line DL2 and the third data line DL3.

In various exemplary embodiments of the present disclosure, the first to fourth data lines DL1, DL2, DL3, and DL4 configure a data line group and extend along the second direction DR2. Further, the first to fourth data lines DL1, DL2, DL3, and DL4 are disposed between the circuit elements and extend along the second direction DR2. The first data line DL1 and the fourth data line DL4 are disposed at the outermost side with respect to the first direction DR1.

Referring to FIGS. 4A and 5, according to the exemplary embodiment, the first data line DL1 and the fourth data line DL4 disposed at the outermost side can be directly connected to the first circuit element BC and the fourth circuit element GC which are adjacent to the data lines. However, in order to connect the first data line DL1 and the fourth data line DL4 to the first circuit element BC and the fourth circuit element GC which are not adjacent, the first data line DL1 and the fourth data line DL4 need to cross at least three data lines.

In order to improve the circuit structure, in one exemplary embodiment, at least some of the first sub pixels BSP is electrically connected to the first data line DL1 via the second data bridge BRI2 and the other first sub pixels BSP are electrically connected to the first data line DL1 regardless of the second data bridge BRI2. Further, in one exemplary embodiment, at least some of the fourth sub pixels GSP is electrically connected to the fourth data line DL4 via the first data bridge BRI1 and the other fourth sub pixels GSP are electrically connected to the fourth data line DL4 regardless of the first data bridge BRI1.

In the meantime, in an example, the second data line DL2 and the third data line DL3 are not connected to any data bridge, but can be electrically connected to the circuit element, but various exemplary embodiments of the present disclosure are not limited thereto. For example, if necessary, a data bridge which is connected to the second data line DL2 and a data bridge which is connected to the third data line DL3 can be further included.

Hereinafter, transistors included in each circuit element and a circuit structure of a display device according to an embodiment of the present disclosure will be described.

Referring to FIG. 5, in one exemplary embodiment, the first circuit element BC includes a first switching transistor SWT1, the second circuit element RC includes a second switching transistor SWT2, the third circuit element WC includes a third switching transistor SWT3, and the fourth circuit element GC can include a fourth switching transistor SWT4.

The first switching transistor SWT1 can include a first source-drain electrode SD1, a first semiconductor layer DA1, and a first gate electrode GAT1. It is understood that the first switching transistor SWT1 further includes another metal electrode which serves as a first source-drain electrode SD1 in a portion opposite to the first source-drain electrode SD1.

The first switching transistor SWT1 can transmit a data signal supplied from the first data line DL1 to the first source-drain electrode SD1. For example, the first switching transistor SWT1 can transmit a data signal to the first source-drain electrode SD1 in response to a gate-on voltage which is applied from the second gate line GL2 to the first gate electrode GAT1. The data signal which is transmitted to the first source-drain electrode SD1 charges the storage capacitor and can determine a gate voltage of the driving transistor.

The second switching transistor SWT2 can include a second source-drain electrode SD2, a second semiconductor layer DA2, and a second gate electrode GAT2. It is understood that the second switching transistor SWT2 further includes another metal electrode which serves as a second source-drain electrode SD2 in a portion opposite to the second source-drain electrode SD2.

The second switching transistor SWT2 can transmit a data signal supplied from the second data line DL2 to the second source-drain electrode SD2. For example, the second switching transistor SWT2 can transmit a data signal to the second source-drain electrode SD2 in response to a gate-on voltage which is applied from the second gate line GL2 to the second gate electrode GAT2. The data signal which is transmitted to the second source-drain electrode SD2 charges the storage capacitor and can determine a gate voltage of the driving transistor.

The third switching transistor SWT3 can include a third source-drain electrode SD3, a third semiconductor layer DA3, and a third gate electrode GAT3. It is understood that the third switching transistor SWT3 further includes another metal electrode which serves as a third source-drain electrode SD3 in a portion opposite to the third source-drain electrode SD3.

The third switching transistor SWT3 can transmit a data signal supplied from the third data line DL3 to the third source-drain electrode SD3. For example, the third switching transistor SWT3 can transmit a data signal to the third source-drain electrode SD3 in response to a gate-on voltage which is applied from the first gate line GL1 to the third gate electrode GAT3. The data signal which is transmitted to the third source-drain electrode SD3 charges the storage capacitor and can determine a gate voltage of the driving transistor.

The fourth switching transistor SWT4 can include a fourth source-drain electrode SD4, a fourth semiconductor layer DA4, and a fourth gate electrode GAT4. It is understood that the fourth switching transistor SWT4 further includes another metal electrode which serves as a fourth source-drain electrode SD4 in a portion opposite to the fourth source-drain electrode SD4.

The fourth switching transistor SWT4 can transmit a data signal supplied from the fourth data line DL4 to the fourth source-drain electrode SD4. For example, the fourth switching transistor SWT4 can transmit a data signal to the fourth source-drain electrode SD4 in response to a gate-on voltage which is applied from the first gate line GL1 to the fourth gate electrode GAT4. The data signal which is transmitted to the fourth source-drain electrode SD4 charges the storage capacitor and can determine a gate voltage of the driving transistor.

Hereinafter, a circuit structure including an emission area of one sub pixel in a display device according to an embodiment of the present disclosure will be described with reference to FIG. 6.

FIG. 6 is a plan view illustrating a circuit structure for driving a sub pixel of the display panel.

Particularly, FIG. 6 will be described with reference to the first sub pixel BSP which has been described with reference to FIG. 4A and the description with reference to FIG. 6 can be applied to the second to fourth sub pixels RSP, WSP, and GSP, as well as the first sub pixel BSP, in the substantially same way. In other words, the description of the first sub pixel BSP can be understood to be the same or similar as the description of a K-th sub pixel (K is 2, 3, and 4).

In one exemplary embodiment, the sub pixel can include a circuit element. The circuit element can include a driving transistor and a switching transistor. Further, the circuit element can include a sensing transistor.

Referring to FIG. 6, in one exemplary embodiment, the driving transistor DT can include a driving gate electrode DG, driving source-drain electrodes DM, and a semiconductor layer DA which connects the driving source-drain electrodes DM. Any one of the driving source-drain electrodes DM can be electrically connected to the high potential voltage line VDDL (specifically, the first connection member CM1 connected to the high potential voltage line VDDL). The other one of the driving source-drain electrodes DM can be electrically connected to the pixel electrode PXE.

In one exemplary embodiment, the switching transistor SWT can include a switching gate electrode SWG, switching source-drain electrodes SWM, and a semiconductor layer SWA which connects the switching source-drain electrodes SWM. Any one of the switching source-drain electrodes SWM can be electrically connected to the data line DL and the other one of the switching source-drain electrodes SWM can be electrically connected to the driving gate electrode DG. The switching source-drain electrode SWM which is electrically connected to the driving gate electrode DG can be electrically connected to one surface of the storage capacitor. One surface of the storage capacitor can be the substantially same node as the driving gate electrode DG.

In one exemplary embodiment, the sensing transistor SET can include a sensing gate electrode SEG, sensing source-drain electrodes SEM, and a semiconductor layer SEA which connects the sensing source-drain electrodes SEM. The switching gate electrode SWG and the sensing gate electrode SEG can share the same or substantially same gate line GL.

In one exemplary embodiment, the driving gate electrode DG can have a shape extending along the second direction DR2. Further, in one exemplary embodiment, the switching gate electrode SWG can have a shape extending along the second direction DR2. In one exemplary embodiment, the driving gate electrode DG and the switching gate electrode SWG can have a shape extending along the substantially same direction (for example, the second direction DR2).

In one exemplary embodiment, the driving source-drain electrode DM is disposed to be adjacent to the data line DL and the high potential voltage line VDDL can be electrically connected to the driving source-drain electrodes DM. Specifically, the high potential voltage line VDDL can be electrically connected to the source-drain electrode DM which is adjacent to the data line DL via the first connection member CM1.

In one exemplary embodiment, the driving gate electrode DG and the switching gate electrode SWG can be disposed on the substantially same line along the first direction DR1. As the driving gate electrode DG and the switching gate electrode SWG are disposed on the substantially same line, a characteristic deviation caused in the driving transistor DT can be minimized.

In one exemplary embodiment, the display panel can include one or more welding points WP as described above with reference to FIGS. 3, 4A, and 4B. The welding point WP can include a first welding point WP1 and a second welding point WP2, and the first welding point WP1 and the second welding point WP2 can be electrically connected to each other. The first welding point WP1 can be connected to the corresponding circuit element through the second connection member CM2 and the second welding point WP2 can be connected to the repair line RL (see the RL of FIG. 4A).

In one exemplary embodiment, a first end of the second connection member CM2 is connected to the reference voltage line RVL, a second end of the second connection member CM2 is connected to the circuit element, and a third end of the second connection member CM2 can be connected to a welding point WP. Further, the second connection member CM2 can be divided into the first branch B1 and the second branch B2 from the branch point BP to connect the configurations located in the first to third ends. Here, the first branch B1 is connected to the first welding point WP1 and the second branch B2 can be connected to the reference voltage line RVL. At least some of the second branch B2 can be used as a semiconductor layer SEA for the sensing transistor SET.

In one exemplary embodiment, the second connection member CM2 can be disposed to intersect the emission area such as BE. The second connection member CM2 can be included in at least a part of the emission area (BE). The second connection member CM2 can have a shape extending along the first direction DR1 over the emission area (BE).

Accordingly, the display device according to various exemplary embodiments of the present disclosure which has been described with reference to FIGS. 1 to 6 can be configured with an efficient layout configuration, which can reduce a load of the data line, as compared with a design which bundles the data lines. For instance, since the data lines DL1-DL4 can be disposed between the pixels PX11, PX12 and PX12, PX22, a more compact display device can be provided. Further, by using components such as connection members CM1, CM2, welding points and repair lines RL that are implemented in an efficient manner, an improved display device that can offer various operations can be provided with improved life span and displaying speed. In addition, due to the compact configuration, aa display device with a large-size OLED display panel which can implements a high driving frequency (e.g., 120 Hz) of double rate driving (DRD) can be provided.

Further, the display device according to various embodiments can minimize a RC delay by adding one or more data bridges such as the data bridges BRI1 and BRI2 of FIG. 5.

Further, the display device according to various embodiments can improve the repair characteristic by adding a welding point such as the welding point WP shown in FIGS. 4A-6.

Further, the display device according to various embodiments can improve a repair characteristic by depositing a pigment on one or more data lines.

Further, the display device according to various embodiments minimizes the characteristic deviation of the driving transistor and the interference with another gate line by a shape extending the sub pixel along the horizontal direction (first direction DR1) and sequentially disposing the plurality of sub pixels along the second direction DR2.

The exemplary embodiments of the present disclosure can also be described as follows.

According to an aspect of the present disclosure, a display device includes a display panel in which a plurality of pixels is disposed; a data driver configured to supply a data signal to the pixels; and a gate driver configured to supply a gate signal to the pixels. The display panel includes data lines, gate lines, and a high potential voltage line, and one or two or more reference voltage lines, each of the pixels includes first to fourth sub pixels and the data lines include first to fourth data lines which supply the data signal to the first to fourth sub pixels, the first to fourth data lines are disposed between circuit elements provided in the first to fourth sub pixels which are disposed to be adjacent along a first direction, the high potential voltage line and one or two or more reference voltage lines are disposed between light emitting diodes provided in the first to fourth sub pixels, and a circuit element and a light emitting diode which configure each of the first to fourth sub pixels can be disposed along a first direction.

The sub pixels and the gate lines can extend along the first direction and the data lines, the reference voltage line, and the high potential voltage line can extend along the second direction orthogonal to the first direction.

The pixel can include a first sub pixel configured to display blue, a second sub pixel configured to display red, a third sub pixel configured to display white, and a fourth sub pixel configured to display green, and the first data line can be connected to a first circuit element of the first sub pixel, the second data line can be connected to a second circuit element of the second sub pixel, the third data line can be connected to a third circuit element of the third sub pixel, and the fourth data line can be connected to a fourth circuit element of the fourth sub pixel.

The display panel can include a first data bridge and a second data bridge, the first data bridge can electrically connect the fourth data line and a fourth circuit element which is located to be away from the fourth data line, and the second data bridge can electrically connect the first data line and a first circuit element which is located to be away from the first data line.

The first data bridge can intersect the second data line and the third data line along a first direction. The second data bridge can intersect the second data line and the third data line along a first direction.

The first to fourth data lines can be disposed between the first circuit element and the second circuit element. The first to fourth data lines can be disposed between the third circuit element and the fourth circuit element.

The high potential voltage line can be electrically connected to first to fourth circuit elements through a first connection member.

The first to fourth data lines can transmit a data signal to the first to fourth circuit elements along a first direction, and the high potential voltage line can transmit a high potential voltage to the first to fourth circuit elements along the first direction as same as the data signal, through the first connection member.

Each of the first to fourth circuit elements can include a switching transistor and a driving transistor, one end of the switching transistor can be connected to any one of data lines, and the other end of the switching transistor can be connected to a gate electrode of the driving transistor, one end of the driving transistor can be connected to the high potential voltage line and the other end of the driving transistor can be connected to a pixel electrode, and the gate lines extend along the first direction and the data lines extend along the second direction.

A gate electrode of the driving transistor can have a shape extending along the second direction. Agate electrode of the switching transistor can be electrically connected to the gate line and the gate electrode of the switching transistor has a shape extending along the second direction.

The first to fourth circuit elements can further include sensing transistors, one end of the sensing transistor can be electrically connected to a source-drain electrode of the driving transistor, the other end of the sensing transistor can be electrically connected to the reference voltage line, and a gate electrode of the sensing transistor can be electrically connected to the gate line.

Agate electrode of the sensing transistor can be formed to be drawn in the same direction as the gate electrode of the switching transistor.

The first to fourth circuit elements can further include a second connection member including first and second branches and first and second welding points, the first branch can connect the driving transistor, the first welding point, and the driving transistor, and the second branch connects the reference voltage line and the driving transistor.

The second connection member can be disposed on an emission area of the sub pixel. The second welding point can be connected to the first welding point included in an adjacent sub pixel configured to display the same color through a repair line.

The repair line can be disposed to intersect the reference voltage line and the high potential voltage line. The repair line can be disposed to be spaced apart from the other repair line.

A display device according to another aspect of the present disclosure can include a display panel including sub pixels, data lines, gate lines crossing the data lines, high potential voltage lines, and reference voltage lines, wherein the sub pixels include a first column of sub pixels and a second column of sub pixels extending along a second direction and being adjacent to each other, the data lines extend along the second direction between the first and second columns of sub pixels, and are disposed at one side of each of the first and second columns of sub pixels, and the high potential voltage lines and at least one of the reference voltage lines extend along the second direction and are disposed at another side of each of the first and second columns of sub pixels.

According to another aspect of the present disclosure, the display panel includes a data bridge configured to electrically connect one of the data lines to one of the sub pixels that is spaced apart from the one of the data lines, and the data bridge extends in the first direction and crosses two other data lines among the data lines.

According to another aspect of the present disclosure, each of the sub pixels includes a light emitting element and a circuit element configured to drive the light emitting element, and at least one of the high potential voltage lines is electrically connected to at least two of the the circuit elements through a connection member.

According to another aspect, the first and second columns of sub pixels include sub pixels configured to display different colors and are connected to first and second gate lines, and a color sequence of the first column of sub pixels connected to the first and second gate lines is different from a color sequence of the second column of sub pixels connected to the first and second gate lines. For instance, in the first column of sub pixels connected to the first and second gate lines (e.g., GL1 and GL2), the blue sub pixel, green sub pixel, red sub pixel and white sub pixel can be disposed in the second direction in such a color sequence, whereas in the second column of sub pixels connected to the same first and second gates, the red sub pixel, white sub pixel, blue sub pixel and green sub pixel can be disposed in the second direction in such a color sequence different from the other color sequence.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto.

Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a display panel including pixels;
a data driver configured to supply a data signal to the pixels; and
a gate driver configured to supply a gate signal to the pixels,
wherein the display panel includes data lines, gate lines, a high potential voltage line, and one or more reference voltage lines,
each of the pixels includes first to fourth sub pixels, and the data lines include first to fourth data lines which supply the data signals to the first to fourth sub pixels, respectively, and extend along a second direction,
each of the first to fourth sub pixels includes a light emitting diode and a circuit element configured to drive the light emitting diode,
the first to fourth data lines are disposed between the circuit elements of two adjacent sub pixels extending along a first direction different from the second direction, among the first to fourth sub pixels, and
the high potential voltage line and the one or two reference voltage lines extend along the second direction.

2. The display device according to claim 1,
wherein the first to fourth sub pixels and the gate lines extend along the first direction, and the second direction is substantially perpendicular to the first direction.

3. The display device according to claim 1,
wherein the first sub pixel is configured to display blue color, the second sub pixel is configured to display red color, the third sub pixel is configured to display white color, and the fourth sub pixel is configured to display green color, and
wherein the first data line is connected to a first circuit element of the first sub pixel, the second data line is connected to a second circuit element of the second sub pixel, the third data line is connected to a third circuit element of the third sub pixel, and the fourth data line is connected to a fourth circuit element of the fourth sub pixel.

4. The display device according to claim 3,
wherein the display panel includes a first data bridge and a second data bridge,
the first data bridge electrically connects the fourth data line and the fourth circuit element spaced apart from the fourth data line, and
the second data bridge electrically connects the first data line and the first circuit element spaced apart from the first data line.

5. The display device according to claim 4,
wherein at least one of the first data bridge and the second data bridge is disposed to intersect the second data line and the third data line along the first direction.

6. The display device according to claim 3,
wherein the two adjacent sub pixels are the first and second sub pixels, and the first to fourth data lines are disposed between the first circuit element of the first sub pixel and the second circuit element of the second sub pixel, or
wherein the two adjacent sub pixels are the third and fourth sub pixels, and the first to fourth data lines are disposed between the third circuit element of the third sub pixel and the fourth circuit element of the fourth sub pixel.

7. The display device according to claim 3,
wherein the high potential voltage line is electrically connected to one or more of the first to fourth circuit elements through a first connection member.

8. The display device according to claim 7,
wherein the first to fourth data lines transmit the data signals to the first to fourth circuit elements, and
the high potential voltage line transmits a high potential voltage to the first to fourth circuit elements along the first direction same as the data signal, through the first connection member extending along the first direction.

9. The display device according to claim 3,
wherein each of the first to fourth circuit elements includes a switching transistor and a driving transistor,
for each of one or more of the first to fourth circuit elements, one end of the switching transistor is connected to one of the data lines, and another end of the switching transistor is connected to a gate electrode of the driving transistor, whereas one end of the driving transistor is connected to the high potential voltage line and another end of the driving transistor is connected to a pixel electrode, and
the gate lines extend along the first direction being substantially perpendicular to the first direction.

10. The display device according to claim 9,
wherein a gate electrode of each driving transistor has a shape extending along the second direction.

11. The display device according to claim 9,
wherein a gate electrode of each switching transistor is electrically connected to one of the gate lines, and the gate electrode of each switching transistor has a shape extending along the second direction.

12. The display device according to claim 9,
wherein the first to fourth circuit elements further include sensing transistors,
each sensing transistor has one end electrically connected to a source-drain electrode of the driving transistor and another end electrically connected to the reference voltage line, and
a gate electrode of each sensing transistor is electrically connected to one of the gate lines.

13. The display device according to claim 12,
wherein the gate electrode of the sensing transistor is formed to extend in a same direction as a gate electrode of the switching transistor.

14. The display device according to claim 9,
wherein the first to fourth circuit elements further include a second connection member including first and second branches and first and second welding points,
the first branch connects the driving transistor, the first welding point, and the driving transistor, and
the second branch connects the reference voltage line and the driving transistor.

15. The display device according to claim 14,
wherein the second connection member is disposed on an emission area of at least one of the first to fourth sub pixels.

16. The display device according to claim 14,
wherein the second welding point is connected to the first welding point included in an adjacent sub pixel configured to display a same color through a repair line.

17. The display device according to claim 16,
wherein the repair line is disposed to intersect the one or more reference voltage lines and the high potential voltage line.

18. The display device according to claim 16,
wherein the repair line is disposed to be spaced apart from another repair line, and crosses one of the gate lines.

19. A display device, comprising:
a display panel including sub pixels, data lines, gate lines crossing the data lines, high potential voltage lines, and reference voltage lines,
wherein the sub pixels include a first column of sub pixels and a second column of sub pixels extending along a second direction and being adjacent to each other,
the data lines extend along the second direction between the first and second columns of sub pixels, and are disposed at one side of each of the first and second columns of sub pixels, and
the high potential voltage lines and at least one of the reference voltage lines extend along the second direction and are disposed at another side of each of the first and second columns of sub pixels.

20. The display device according to claim 19,
wherein the display panel includes a data bridge configured to electrically connect one of the data lines to one of the sub pixels that is spaced apart from the one of the data lines, and
the data bridge extends in the first direction and crosses two other data lines among the data lines.

21. The display device according to claim 19,
wherein each of the sub pixels includes a light emitting element and a circuit element configured to drive the light emitting element, and
at least one of the high potential voltage lines is electrically connected to at least two of the the circuit elements through a connection member.

22. The display device according to claim 19,
wherein the first and second columns of sub pixels include sub pixels configured to display different colors and are connected to first and second gate lines, and
a color sequence of the first column of sub pixels connected to the first and second gate lines is different from a color sequence of the second column of sub pixels connected to the first and second gate lines.
